(19) United States
(12) Patent Application Publication
(10) Pub. No.: US 2009/0289297 A1
(43) Pub. Date: Nov. 26, 2009

(54) CHARGE TRAP-TYPE NON-VOLATILE MEMORY DEVICE AND METHOD OF FABRICATING THE SAME

(75) Inventors: Kwang-Ok KIM, Icheon-si (KR); Hye-Ran Kang, Icheon-si (KR)

Correspondence Address: LOWE HAUPTMAN HAM & BERNER, LLP, 1700 DIAGONAL ROAD, SUITE 300, ALEXANDRIA, VA, 22314, US

(73) Assignee: Hynix Semiconductor Inc., Icheon-si (KR)

(21) Appl. No.: 12/333,253

(22) Filed: Dec. 11, 2008

(30) Foreign Application Priority Data
May 21, 2008 (KR) 10-2008-0047079

(51) Int. Cl. H01L 29/78; H01L 21/3205

(52) U.S. Cl. 257/324; 438/591; 257/E29.255; 257/E21.409

(57) ABSTRACT

A charge trap-type non-volatile memory device, and related method, includes forming over a substrate a tunnel insulating layer, a charge trapping layer, a dielectric layer, and a conductive layer for a gate electrode; forming a gate electrode by selectively etching the conductive layer for the gate electrode; forming a spacer including a first spacer and a second spacer on a sidewall of the gate electrode, the second spacer being formed of material different from that of the first spacer; and etching the dielectric layer and the charge trapping layer by using the spacer as an etching barrier, thereby preventing an attack to the gate electrode when etching the charge trapping layer and thus enhancing reliability and stability of transistors. In addition, in one or more embodiments, a sidewall of the charge trapping layer pattern is formed vertically, thereby preventing formation of a tail and an attack to the substrate.

### CROSS-REFERENCE TO RELATED APPLICATIONS

The present application claims priority of Korean patent application number 10-2008-0047079, filed on May 21, 2008, which is incorporated herein by reference in its entirety.

### BACKGROUND

The disclosure relates to a semiconductor device, and more particularly, to a charge trap-type non-volatile memory device, and method of fabricating the same.

A non-volatile memory device maintains storage data intact even when a power supply is cut off, and is classified as a floating gate type device or a charge trap type device depending on a data storing type.

The floating gate type non-volatile memory device sometimes includes a tunnel insulating layer, floating gate, dielectric layer, and control gate over a substrate, and stores data by injecting charges into the floating gate or discharging charges from the floating gate.

When the tunnel insulating layer is attacked, electrons stored within the floating gate escape, causing a loss of the storage data. To prevent such data loss, the floating gate type non-volatile memory device sometimes has a relatively thick tunnel insulating layer. However, when a thickness of the tunnel insulating layer becomes larger, a higher operating voltage is typically required. This in turn often makes peripheral circuits complicated and results in the floating gate type having limitations with respect to a high integration.

In contrast, the charge trap-type non-volatile memory device sometimes includes a tunnel insulating layer, charge trapping layer, dielectric layer, and gate electrode over a substrate. The charge trap type stores data by storing or erasing charges in a deep level trap site of the charge trapping layer. Thus, the stored-charges are not lost even with a relatively thin tunnel insulating layer. Accordingly, in various embodiments, the charge trap-type memory device is driven at a relatively low operating voltage. Accordingly, in one or more embodiments of the charge trap-type non-volatile memory, a higher integration of semiconductor devices is achieved as compared with various embodiments of the floating gate type non-volatile memory.

In one or more embodiments, a charge trap-type non-volatile memory device is configured to share the charge trapping layer between adjacent transistors. Under this configuration, a portion of charges stored in the charge trapping layer moves horizontally. This movement causes an attack to the storage data.

Therefore, in one or more embodiments, respective transistors have mutually separated charge trapping layers by forming a charge trap of an island shape. Such embodiments prevent attacks to data caused by the horizontal transfer of charge. Hereinafter, one or more embodiments of a related method for forming a charge trap-type non-volatile memory device and problems thereof will be described in detail, with reference to the accompanying drawings.

FIGS. 1A to 1E are cross-sectional views depicting a first embodiment of a charge trap-type non-volatile memory device in various stages of fabricating the same.

Referring to FIG. 1A, a tunnel insulating layer 110 is formed over a substrate 100. The tunnel insulating layer 110 is provided herein as an energy barrier layer based on a tunneling of charges, and is formed of an oxide layer.

Subsequently, a charge trapping layer 120 is formed over the tunnel insulating layer 110. The charge trapping layer 120 actually serves herein as a place for data storage by storing the charges that tunnel through the tunnel insulating layer 110. Therefore, the charge trapping layer 120 is formed as a material layer with a plurality of trap sites, and is generally formed of nitride.

Then, a dielectric layer 130 is formed over the charge trapping layer 120. The dielectric layer 130 serves herein as a protection layer to prevent charges from moving upwards through the charge trapping layer 120.

Subsequently, a conductive layer 140 for a gate electrode and then a hard mask layer 150 are sequentially formed over the dielectric layer 130.

With reference to FIG. 1B, a photoresist pattern (not shown) for a gate electrode is formed over the hard mask layer 150. The photoresist pattern is formed such that the gate electrode is adapted to be arranged in an island shape along a first direction and a second direction intersecting the first direction.

Then the hard mask layer 150 and the conductive layer 140 for a gate electrode are etched by using the photoresist pattern as an etching barrier, thereby forming a hard mask pattern 150A and a gate electrode 140A.

As illustrated in FIG. 1C, an insulating layer for a spacer is deposited over the resultant structure with the hard mask pattern 150A and the gate electrode 140A formed therein. The insulating layer for a spacer is formed of nitride in one or more embodiments.

After that, the insulating layer for a spacer is spacer-etched, thereby forming a spacer 160 on a sidewall of the hard mask pattern 150A and the gate electrode 140A.

As illustrated in FIG. 1D, the dielectric layer 130 is etched by using the hard mask pattern 150A and the spacer 160 as an etching barrier. This forms a dielectric layer pattern 130A. During this process, the spacer 160 formed on the sidewall of the hard mask pattern 150A and the gate electrode 140A is sometimes partially attacked.

As shown in FIG. 1E, the charge trapping layer 120 is etched by using the hard mask pattern 150A and the spacer 160 as an etching barrier, thereby forming a charge trapping layer pattern 120A.

However, when the charge trapping layer 120 and the spacer 160 are all formed of nitride, the spacer 160 is sometimes also attacked during the etching process of the charge trapping layer 120. When this occurs to a sufficient degree, the gate electrode 140A is exposed. Additionally, when the gate electrode is formed of tungsten (W), it is easily oxidized with heat. Thus, the gate electrode is sometimes attacked in a subsequent heat treatment process. This is shown by reference character A. In this case, a transistor may not operate or one ore more operational characteristics of the memory device deteriorate.

Furthermore, with respect to the etching process of the charge trapping layer 120, when an etching selection ratio between an oxide layer and a nitride layer is below a certain threshold, the tunnel insulating layer 110 exposed through the etching of the charge trapping layer 120 is attacked. In particular, in a general Self-Aligned Contact (SAC) etch, the oxide layer is etched more than the nitride layer. When this occurs, the tunnel insulating layer 110 and the substrate 100 is attacked.

Accordingly, in one or more embodiments, when it is desirable to selectively etch the charge trapping layer 120 without attacking the tunnel insulating layer 110 and the substrate 100, the charge trapping layer 120 is etched under conditions where the etching selection ratio of the oxide layer and the nitride layer is above a certain threshold. In other words, an etch rate of the nitride layer increases when etching the charge trapping layer 120.

However, when the etching selection ratio between the nitride layer and the oxide layer is increased, there is a problem in that the sidewall of the charge trapping layer pattern 120A does not form a square corner with the tunnel insulating layer 110, but forms a tail shown by reference character B. Meanwhile, when performing an over-etching to eliminate the tail B, the tunnel insulating layer 110 is attacked, causing an attack to the substrate 100 thereunder as shown by reference character C.

FIGS. 2A, 2B and 2C are photographic pictures depicting cross sectional views of a second embodiment of a charge trap-type nonvolatile memory device FIGS. 2A, 2B and 2C are photographic pictures depicting cross section views of a second embodiment of a charge trap-type non-volatile memory device.

As shown in FIG. 2A, a spacer is attacked when etching the charge trapping layer by using the spacer formed of nitride as an etching barrier. This causes an attack to the gate electrode as shown by reference character A.

As shown in FIG. 2B, when increasing an etching selection ratio between the nitride layer and the oxide layer during the etching process of the charge trapping layer, the tail shown by reference character B is formed on a sidewall of the charge trapping layer pattern. In one or more embodiments, the formation of the tail B may cause a mutual connection between adjacent charge trapping layer patterns. This mutual connection causes a degradation in the performance of the memory devices.

As shown in FIG. 2C, when performing an over-etching to prevent the formation of the tail B, the tunnel insulating layer and the substrate are attacked as shown by reference character C. Such an attack to the substrate is sometimes referred to as a punch. The punch effect is generated randomly over the substrate 100. This too causes a degradation in the performance of the memory devices.

### SUMMARY

In accordance with one or more embodiments, a method for fabricating a memory device using a spacer combined with an oxide layer and a nitride layer, which is capable of preventing a gate electrode and a substrate from being attacked by an attack to the spacer when etching the charge trapping layer, is provided.

One or more embodiments are described below with reference to the accompanying drawings. Various exemplary embodiments may, however, take many different forms and should not be construed as being limited to the embodiments set forth herein; rather, these embodiments are provided so that this disclosure is thorough and complete, and conveys the inventive concept to those skilled in the art.

In accordance with one or more embodiments, a method for fabricating a charge trap-type non-volatile memory device includes forming over a substrate a tunnel insulating layer, a charge trapping layer, a dielectric layer and a conductive layer for a gate electrode; forming a gate electrode by selectively etching the conductive layer for gate electrode; forming a spacer including a first spacer and a second spacer on a sidewall of the gate electrode, the second spacer being formed of material different from that of the first spacer; and etching the dielectric layer and the charge trapping layer by using the spacer as an etching barrier.

In accordance with one or more embodiments, a charge trap-type non-volatile memory device includes a substrate; a tunnel insulating layer, a charge trapping layer, a dielectric layer, and a conductive layer for a gate electrode, formed over the substrate; and a spacer including a first spacer and a second spacer on a sidewall of the gate electrode, the second spacer being formed of material different from a material of the first spacer.

In accordance with one or more embodiments, an exposure of the gate electrode caused by the attack to the spacer is prevented by forming the spacer combined with an oxide layer and a nitride layer on a sidewall of the gate electrode. In accordance with one or more embodiments, the attack to the gate electrode occurring in a subsequent heat treatment process is prevented, thereby enhancing reliability and stability of transistors.

In accordance with one or more embodiments, a sidewall of a charge trapping layer pattern is etched vertically through an isotropic etching in a condition where an etching selection ratio is relatively high between an oxide layer and a nitride layer, thereby preventing the formation of a tail and an attack to the substrate. Accordingly, in accordance with one or more embodiments, characteristics of memory devices are improved and a yield of fabricating processes of the memory device increases.

### BRIEF DESCRIPTION OF THE DRAWINGS

Various embodiments are illustrated by way of example, and not by limitation, in the figures of the accompanying drawings.

FIGS. 1A to 1E are cross-sectional views depicting a first embodiment of a charge trap-type non-volatile memory device in various stages of fabricating the same.

FIGS. 2A, 2B and 2C are photographic pictures depicting cross sectional views of a second embodiment of a charge trap-type nonvolatile memory device.

FIGS. 3A to 3E are cross-sectional views depicting a third embodiment of a charge trap-type non-volatile memory device in various stages of fabricating the same.

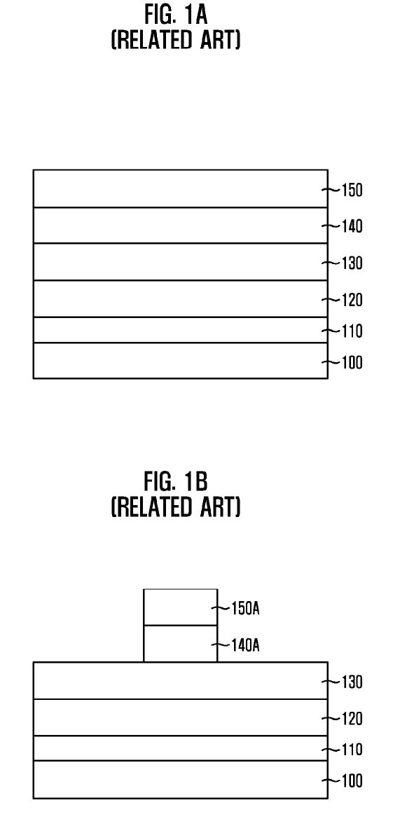

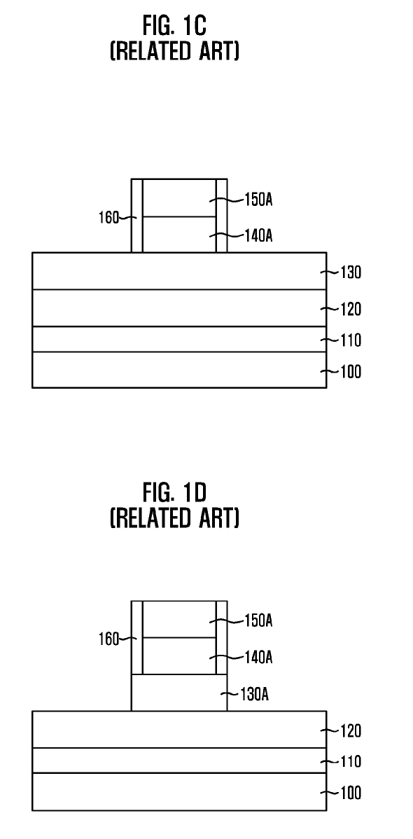

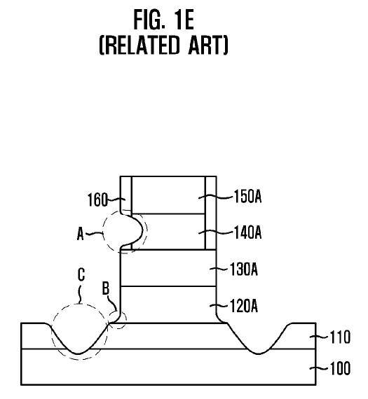

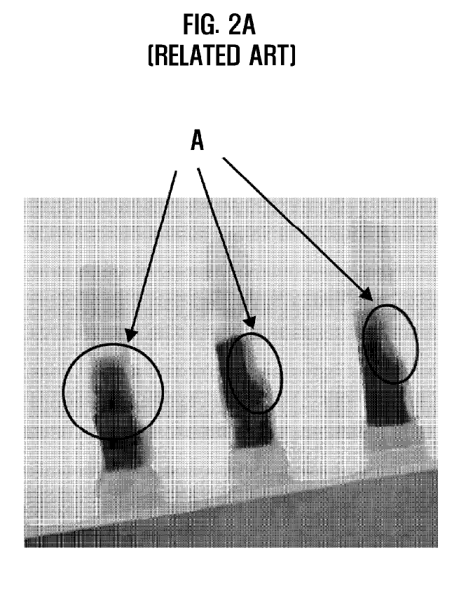

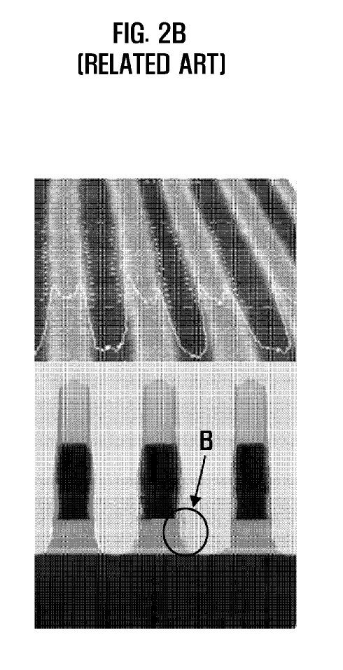

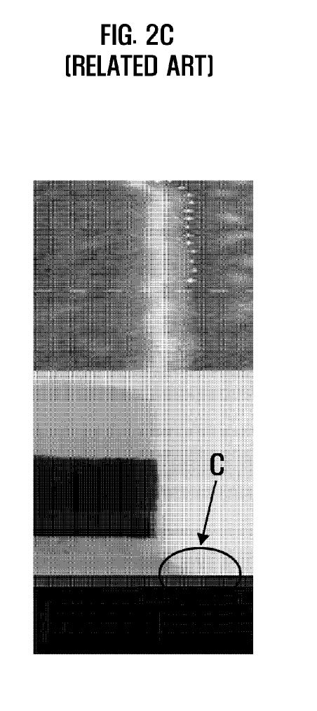

### DESCRIPTION OF EMBODIMENTS

Other objects and advantages of one or more embodiments can be understood by the following description, and become apparent with reference to one or more embodiments. In the drawings, like components having like functions have been provided with like reference symbols and numerals.

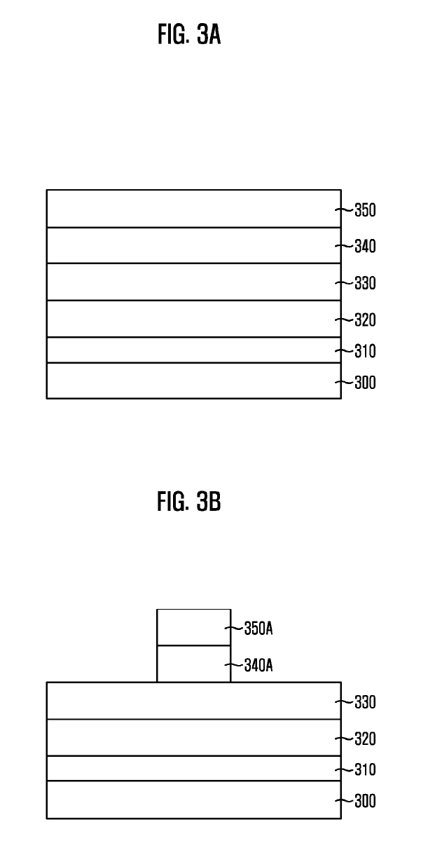

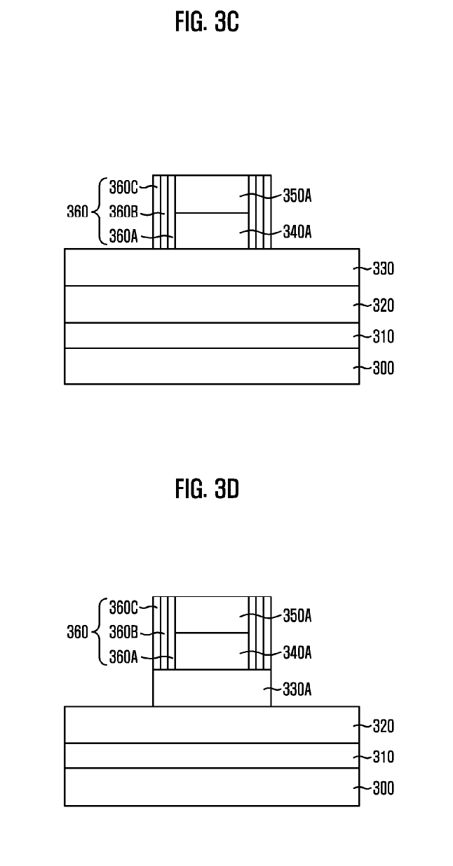

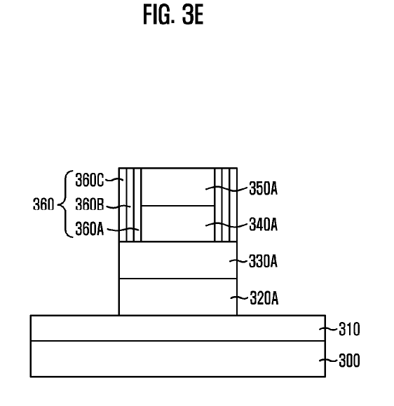

FIGS. 3A to 3E are cross-sectional views depicting a third embodiment of a charge trap-type non-volatile memory device in various stages of fabricating the same.

As shown in FIG. 3A, a tunnel insulating layer 310 is formed over a substrate 300. The tunnel insulating layer 310 is provided as an energy barrier layer based on a tunneling effect of charges. In one or more embodiments, the tunnel insulating layer 310 is formed of an oxide layer. In one or more embodiments, the tunnel insulating layer 310 is formed with a thickness of approximately 10 Angstroms to approximately 100 Angstroms.

Subsequently, a charge trapping layer 320 is formed over the tunnel insulating layer 310. Here, the charge trapping layer 320 actually serves as a place for storing data by storing charges which tunnel through the tunnel insulating layer 310. Therefore, the charge trapping layer 320 is formed of a material with a plurality of trap sites. In one or more embodiments, the charge trapping layer is formed of nitride. In one or more embodiments, the charge trapping layer 320 is formed of a thickness of approximately 20 Angstroms to approximately 100 Angstroms.

Then, a dielectric layer 330 is formed over the charge trapping layer 320. Here, the dielectric layer 330 serves as a protection layer to prevent charges from moving upwards through the charge trapping layer 320. In one or more embodiments, the dielectric layer 330 is formed to have a thickness of approximately 40 Angstroms to approximately 100 Angstroms by using an insulating layer with a high dielectric constant-k of approximately 10 or more.

In particular, when forming the dielectric layer 330 by using a metal oxide with a relatively high dielectric constant, in one or more embodiments, a read and write operating speed of the memory device increases and a data retention characteristic is improved. In one or more embodiments, the dielectric layer 330 is more formed of one of Al₂O₃, HfO₂, ZrO₂, Y₂O₃ and La₂O₃ or of a combination of these compounds.

Subsequently, a conductive layer 340 for a gate electrode is formed over the dielectric layer 330. In one or more embodiments, the conductive layer 340 for a gate electrode is formed of a single layer or double layer, and, in one or more embodiments, the conductive layer 340 is formed of one of WSix, CoSix, NiSix, polysilicon, TaN, and TiN or of a combination of these compounds. Particularly, when forming the conductive layer 340 for a gate electrode as the double layer, in one or more embodiments, a conductive layer formed of polysilicon, TaN or TiN is formed with a thickness of approximately 200 Angstroms to approximately 1000 Angstroms on a lower part thereof, and on the upper part thereof, a conductive layer formed of WSix, CoSix, or NiSix is formed with a thickness of approximately 200 Angstroms to approximately 1500 Angstroms.

Then, a hard mask layer 350 is formed over the conductive layer 340 for a gate electrode. In one or more embodiments, the hard mask layer 350 is formed with a thickness of approximately 500 Angstroms to approximately 3000 Angstroms by using an oxide or nitride layer.

As shown in FIG. 3B, a photoresist pattern (not shown) for a gate electrode is formed over the hard mask layer 350. The photoresist pattern is formed such that the gate electrode is adapted to be arranged in an island shape along a first direction and a second direction intersecting the first direction.

Subsequently, the hard mask layer 350 and the conductive layer 340 for a gate electrode are etched by using the photoresist pattern as an etching barrier, thereby forming a hard mask pattern 350A and a gate electrode 340A.

As shown in FIG. 3C, an insulating layer for a first spacer, an insulating layer for a second spacer formed of material different from the insulating layer for a first spacer, and an insulating layer for a third spacer, formed of material different from the insulating layer for a second spacer, are sequentially deposited over the structure with the hard mask pattern 350A and the gate electrode 340A. In this manner, a triple insulating layer for spacers is formed.

In one or more embodiments, the insulating layer for a first spacer is formed of nitride, the insulating layer for a second spacer is formed of oxide, and the insulating layer for a third spacer is formed of nitride.

Then, the insulating layer for a spacer is spacer-etched, thereby forming a spacer 360 on a sidewall of the hard mask pattern 350A and the gate electrode 340A. At this time, the insulating layer for a spacer formed of the triple layer is spacer-etched, thereby producing the spacer 360 of the triple layer that includes a first spacer 360A in contact with a sidewall of the gate electrode 340A, a second spacer 360B in contact with an outer wall of the first spacer 360A, and a third spacer 360C in contact with an outer wall of the second spacer 360B.

As described above, the spacer 360 of the triple layer may be formed including the first spacer 360A formed of nitride, the second spacer 360B formed of oxide and the third spacer 360C formed of nitride.

As illustrated in FIG. 3D, the dielectric layer 330 is etched by using the hard mask pattern 350A and the spacer 360 as an etching barrier, thereby forming a dielectric layer pattern 330A. At this time, the spacer 360 may be attacked when etching the dielectric layer 330.

As shown in FIG. 3E, the charge trapping layer 320 is etched by using the hard mask pattern 350A and the spacer 360 as an etching barrier, thereby forming a charge trapping layer pattern 320A.

As described above, when the charge trapping layer 320 and the third spacer 360C are all formed of nitride, the third spacer 360C is attacked when etching the charge trapping layer 320 in one or more embodiments. However, the second spacer 360B formed of oxide is not attacked when etching the charge trapping layer 320. Thus, the gate electrode 340A is not exposed. This prevents an attack on the gate electrode 340A.

In addition, in one or more embodiments, the charge trapping layer 320 is etched in a condition where an etching selection ratio between the nitride layer and the oxide layer is relatively high, that is, a condition where an etch rate of nitride layer is above a certain threshold, thereby preventing the tunnel insulating layer 310 and the substrate 300 from being attacked. In one or more embodiments, an etching process of the charge trapping layer 320 is performed by using CF₄ gas, CHF₃ gas, CH₂F₂ gas, CH₃F gas, C₄F₆ gas, or C₄F₈ gas. Particularly, in one or more embodiments, the etching selection ratio between the nitride layer and oxide layer is raised by using an etching gas having a high rate of F such as CH₂F₂ gas or CH₃F gas.

Furthermore, the charge trapping layer 320 is etched in an isotropic way, thereby preventing the formation of a tail on the sidewall of the charge trapping layer 320.

In the above-description the spacer 360 is described as the triple layer comprising the first spacer 360A which is formed of nitride, the second spacer 360B which is formed of oxide, and the third spacer 360C which is formed of nitride. However, it should be apparent that one or more other embodiments vary diversely.

For example, when the spacer is formed as the triple layer comprising first, second, and third spacers formed sequentially, in one or more embodiments, the first spacer is formed of oxide, the second spacer is formed of nitride, and the third spacer is formed of oxide. In some such embodiments, the third spacer is attacked when etching the dielectric layer, and the second spacer is attacked when etching the charge trapping layer. However, the first spacer formed in a lower part is maintained so as not to expose the gate electrode, thereby preventing an attack to the gate electrode.

One or more embodiments relate to a method for fabricating a charge trap-type non-volatile memory device. According to one or more embodiments, when the spacer is sequentially formed of a double layer including first and second layers, the first spacer is formed of oxide and the second spacer is formed of nitride. In some such embodiments, the second spacer is attacked when etching the charge trapping layer, but the gate electrode is protected by the first spacer, thereby preventing an attack to the gate electrode.

While one or more specific embodiments have been described, it will be apparent to those skilled in the art that various changes and modifications may be made.

What is claimed is:

1. A method of fabricating a charge trap-type non-volatile memory device, the method comprising:
forming over a substrate a tunnel insulating layer, a charge trapping layer, a dielectric layer, and a conductive layer for a gate electrode;
forming the gate electrode by selectively etching the conductive layer;
forming a spacer including a first spacer and a second spacer on a sidewall of the gate electrode, the second spacer being formed of material different from a material of the first spacer; and
etching the dielectric layer and the charge trapping layer by using the spacer as an etching barrier.

2. The method of claim 1, wherein forming the spacer includes:
forming an insulating layer for the first spacer over a structure with the gate electrode formed therein;
forming an insulating layer for the second spacer over the insulating layer for the first spacer; and
forming a spacer on the sidewall of the gate electrode by spacer-etching the insulating layers for the first spacer and the second spacer.

3. The method of claim 2, wherein the first spacer is formed of an oxide layer, and the second spacer is formed of a nitride layer.

4. The method of claim 1, wherein the spacer further includes a third spacer which is in contact with an outer wall of the second spacer and formed of a material different from a material of the second spacer.

5. The method of claim 4, wherein the spacer is formed by:
forming an insulating layer for the first spacer over a structure with the gate electrode formed therein;
forming an insulating layer for the second spacer over the insulating layer for the first spacer;
forming an insulating layer for the third spacer over the insulating layer for the second spacer; and
forming a spacer on the sidewall of the gate electrode by spacer-etching the insulation layers for the third, second, and first spacers.

6. The method of claim 5, wherein the first spacer is formed of an oxide layer, the second spacer is formed of a nitride layer, and the third spacer is formed of an oxide layer.

7. The method of claim 5, wherein the first spacer is formed of a nitride layer, the second spacer is formed of an oxide layer, and the third spacer is formed of a nitride layer.

8. The method of claim 1, wherein the charge trapping layer is formed of a nitride layer.

9. The method of claim 8, wherein the tunnel insulating layer is formed of an oxide layer.

10. The method of claim 8, wherein etching the charge trapping layer is performed in a condition where an etching selection ratio between the nitride and the oxide is above a certain threshold.

11. The method of claim 10, wherein etching the charge trapping layer is performed by using a gas selected from the group consisting of CH₂F₂ gas and CH₃F gas.

12. The method of claim 1, wherein the dielectric layer is formed of a metal oxide.

13. The method of claim 12, wherein the dielectric layer is formed of a compound selected from the group consisting of Al₂O₃, HfO₂, ZrO₂, Y₂O₃, and La₂O₃, and combinations thereof.

14. The method of claim 1, wherein the conductive layer for a gate electrode is formed of a compound selected from the group consisting of WSix, CoSix, NiSix, polysilicon, TaN, and TiN, and combinations thereof.

15. A charge trap-type non-volatile memory device, comprising:
a substrate;
a tunnel insulating layer, a charge trapping layer, a dielectric layer, and a conductive layer for a gate electrode, formed over the substrate; and
a spacer including a first spacer and a second spacer on a sidewall of the gate electrode, the second spacer being formed of material different from a material of the first spacer.

16. The charge trap-type non-volatile memory device of claim 15, wherein the spacer includes:
an insulating layer for the first spacer over a structure with the gate electrode formed therein;
an insulating layer for the second spacer over the insulating layer for the first spacer; and
a spacer on the sidewall of the gate electrode.

17. The charge trap-type non-volatile memory device of claim 16, wherein the first spacer is formed of an oxide layer, and the second spacer is formed of a nitride layer.

18. The charge trap-type non-volatile memory device of claim 15, wherein the spacer further includes a third spacer which is in contact with an outer wall of the second spacer and formed of a material different from a material of the second spacer.

19. The charge trap-type non-volatile memory device of claim 18, wherein the spacer further includes:
an insulating layer for the first spacer over a structure with the gate electrode formed therein;
an insulating layer for the second spacer over the insulating layer for the first spacer; and
an insulating layer for the third spacer over the insulating layer for the second spacer.

20. The charge trap-type non-volatile memory device of claim 19, wherein the first spacer is formed of an oxide layer, the second spacer is formed of a nitride layer, and the third spacer is formed of an oxide layer.

21. The charge trap-type non-volatile memory device of claim 19, wherein the first spacer is formed of a nitride layer, the second spacer is formed of an oxide layer, and the third spacer is formed of a nitride layer.

22. The charge trap-type non-volatile memory device of claim 15, wherein the charge trapping layer is formed of a nitride layer.

23. The charge trap-type non-volatile memory device of claim 22, wherein the tunnel insulating layer is formed of an oxide layer.

24. The charge trap-type non-volatile memory device of claim 15, wherein the dielectric layer is formed of a metal oxide.

25. The charge trap-type non-volatile memory device of claim 24, wherein the dielectric layer is formed of a compound selected from the group consisting of Al₂O₃, HfO₂, ZrO₂, Y₂O₃, and La₂O₃, and combinations thereof.

26. The charge trap-type non-volatile memory device of claim 15, wherein the conductive layer for a gate electrode is formed of a compound selected from the group consisting of WSix, CoSix, NiSix, polysilicon, TaN, and TiN, and combinations thereof.
